(19) United States
(12) Patent Application Publication
(10) Pub. No.: US 2006/0234449 A1
(43) Pub. Date: Oct. 19, 2006

(54) FLASH GATE STACK NOTCH TO IMPROVE COUPLING RATIO

(76) Inventor: Michael C. Smayling, Sunnyvale, CA (US)

Correspondence Address: PATTERSON & SHERIDAN, LLP, 3040 POST OAK BOULEVARD, SUITE 1500, HOUSTON, TX, 77056, US

(21) Appl. No.: 11/420,919

(22) Filed: May 30, 2006

Related U.S. Application Data
(62) Division of application No. 10/966,606, filed on Oct. 14, 2004.

(51) Int. Cl. H01L 21/336

(52) U.S. Cl. 438/257

(57) ABSTRACT

A semiconductor flash memory device with increased gate coupling ratio and a method of preparing this flash memory device. The semiconductor flash memory device includes a notched floating polysilicon gate. The notches are at the interface between the floating polysilicon layer and the tunneling dielectric layer. The notches reduce the capacitance between the floating polysilicon and the channel region. The reduced capacitance results in the increased gate coupling ratio. The degree of capacitance reduction, which affects the gate coupling ratio increase, is controlled by the width of the notches. The floating polysilicon gate etch includes a first anisotropic etch and a second isotropic etch. The widths of the notches are controlled by the etch time of the isotropic etch.

### CROSS-REFERENCE TO RELATED APPLICATIONS

This application is a divisional of co-pending U.S. patent application Ser. No. 10/966,606, filed Oct. 14, 2004 (APPM/5145), which is incorporated herein by reference.

### BACKGROUND OF THE INVENTION

1. Field of the Invention

Embodiments of the present invention generally relate to a semiconductor flash memory device and a method for the semiconductor flash memory device. More particularly, the embodiments of the present invention relate to a flash memory device and a method of making the device with increased coupling ratio compared to the conventional flash memory device.

2. Description of the Related Art

Memory devices are largely divided into volatile memory devices, which lose data when power is removed, and non-volatile memory devices, in which the stored information is retained without external power. For non-volatile memory devices, there are read-only memories (ROMs), erasable programmable ROMs (EPROMs) and electrically erasable programmable ROMs (EEPROMs).

Among the non-volatile memory devices, the ROMs are devices in which programming is done during manufacturing by a masking step. The EPROMs and EEPROMs are devices which can erase the stored information and be programmed again to store new information. For EPROMs and EEPROMs, the operations of programming information are similar, but the methods for erasing the stored information are different from each other. In other words, the EPROMs erase the stored information with ultraviolet (UV) light, while the EEPROMs erase the stored information electrically.

Flash memory is one type of EEPROM. Programming a flash cell is accomplished by channel hot electrons, while erasing a flash cell is accomplished by Fowler-Nordheim tunneling. FIGS. 1A to 1C are cross-sectional views illustrating a method for manufacturing a conventional flash memory device. As shown in FIG. 1C, a floating gate 23 and a control gate 25 are stacked on a P-type silicon substrate 20. At a source region 27 and a drain region 28, first and second n-type impurity regions 27 and 28 are formed in the P-type silicon substrate 20 on both sides of the floating gate 23.

Between the floating gate 23 and the control gate 25, an interlayer oxide film 24 is formed with a thickness corresponding to a gate insulating film of a general transistor. Between the floating gate 23 and the P-type silicon substrate 20, a thin tunnel oxide film 22 is formed.

A method for manufacturing such a conventional flash device will be described below. As shown in FIG. 1A, on a P-type silicon substrate 20, a tunnel oxide film 22, a first polysilicon 23, an interlayer oxide film 24 and a second polysilicon 25 are deposited sequentially. As shown in FIG. 1B, a photoresist film 26 is deposited on the second polysilicon 25. Then, through exposure and development process, a control gate region and a floating gate region are defined. As shown in FIG. 1C, using the defined photoresist film 26 as a mask, the second polysilicon 25, interlayer oxide film 24, first polysilicon 23 and tunnel oxide film 22 are selectively removed to form a control gate 25g and a floating gate 23g. Then, using the control gate 25g and floating gate 23g as a mask, n-type impurity ions of high concentration are implanted into the P-type silicon substrate 20, thereby forming first and second impurity regions 27 and 28. The area between the source 27 and drain 28 and right under the tunneling oxide is channel region 21. The operation of the conventional flash device having the EPROM Tunneling Oxide (ETOX) is as follows.

FIGS. 2A and 2B are schematic view illustrating operations for programming and erasing data in the conventional flash memory device. In order to write a data into one cell, as shown in FIG. 2A, a voltage of 7˜8V is applied to the second impurity region 28. A voltage pulse of 12˜13V is applied to the control gate 25g, and the first impurity region 27 and P-type silicon substrate 20 are grounded. Then, a high electric field is created at the drain end of the channel, heating the electrons and causing avalanching.

Some of the hot electrons have energy higher than the energy barrier height (about 3.2V) between the P-type silicon substrate 20 and the tunnel oxide film 22. Thus, some of the hot electrons are injected into the floating gate 23g from the P-type silicon substrate 20 through the tunnel oxide film 22, and stored therein. Such a method is called the channel hot electron injection method. This results in a cell having a logic “0” state in the binary system.

Referring to FIG. 2B, in order to erase the data written in the cell by the above described method, the P-type silicon substrate 20 and control gate 25g are grounded. A voltage pulse of 12˜13V is applied to the first impurity region 27. Then, through the portion of the thin tunnel oxide film 22 where the floating gate 23g overlaps the first impurity region 27, the electrons are discharged from the floating gate 23g into the first impurity region 27 by Fowler-Nordheim tunneling. Fowler-Nordheim tunneling dominantly occurs when the thickness of a tunneling oxide (e.g. tunnel oxide film 22) is below about 100 nm and the applied e-field is greater than 5 MV/cm. Fowler-Nordheim tunneling allows the electrons to be injected into the conduction band of the tunneling oxide by tunneling and thus into the impurity region.

At this time, as the quantity of electrons discharging from the floating gate 23g is increased gradually, the threshold voltage of the cell becomes lower gradually. In general, erasing of the stored data is carried out so that the threshold voltage of the cell is maintained at 3V or less. Accordingly, a logic “1” state is provided in the binary system. In the EEPROM device having the conventional ETOX, a random access is possible when reading a data. Thus, the time required for reading the data can be relatively short.

The flash device having the conventional ETOX has the gate coupling ratio (CR) as follows. The coupling ratio represents a voltage in the floating gate induced by an external voltage applied to the control gate. Therefore, the greater the capacitance between the control gate and the floating gate, the greater the coupling ratio will be. Equation (1) shows that gate coupling ratio (CR) as a function of the relevant capacitances of flash cell.
CR=C_{cg}/(C_{cg}+C_{fs}+C_{fw}+C_{fd}+Cₘₒₛ) (1)
Here, CR is the floating gate to control gate coupling ratio (or gate coupling ratio), C_{cg} represents the capacitance between the control gate 25g and the floating gate 23g, C_{fs} represents the capacitance between the source and the floating gate 23g, C_{fw} represents the capacitance between the substrate 20 and the floating gate 23g, C_{fd} represents the capacitance between the drain and the floating gate 23g, and Cₘₒₛ represent the capacitance between the channel region 21 and the floating gate 23 (or the metal-oxide-semiconductor MOS transistor).

It is desirable to have a high gate coupling ratio so that the voltage applied to the control gate could be reduced to achieve the programming threshold voltage. A reduction in the control gate voltage could reduce the power consumption and also reduce the power source area on the chip that is dedicated to produce the control gate voltage.

To obtain the high gate coupling ratio, the capacitance between the control gate and the floating gate (C_{cg}) need to be increased or other capacitances, such as C_{fs}, C_{fw}, C_{fd} and Cₘₒₛ, need to be decreased. By increasing the cell size, the capacitance between the control gate and the floating gate can be increased. But, increasing the cell size causes a great difficulty in high density device packing. Therefore, in the conventional flash memory, a high voltage must be applied to the drain in an attempt to compensate for the low coupling ratio. As a result, the conventional flash has problems in that they consume high power and are less reliable for effective programming.

Therefore, there is a need for a method of increasing the coupling ratio of a flash cell to reduce the programming voltage without increasing the cell size.

### SUMMARY OF THE INVENTION

The embodiments present invention generally relates a semiconductor flash memory device and a method of making the flash memory device with increased gate coupling ratio. In one embodiment, a semiconductor flash memory device comprises a semiconductor substrate, a tunneling dielectric film formed on said semiconductor substrate, a first gate film and a second gate film on said tunneling film, wherein the first gate film is adjacent and on top of the tunneling film and the second gate film is on top of the first gate film, the first gate film has notches at the interface with the tunneling dielectric film and at the edge of the device, and the heights of the notches are smaller than the thickness of the first gate film, and an interlayer dielectric film between said first gate film and said second gate film.

In another embodiment, a method of increasing the gate coupling ratio of a semiconductor flash memory cell comprises depositing a tunneling dielectric film on said semiconductor substrate, depositing a first gate film on said tunneling dielectric film, depositing an interlayer dielectric film on said first gate film, depositing a second gate film on said interlayer dielectric film, patterning the semiconductor substrate after the second gate film is deposited, etching the second gate film and the interlayer dielectric film, etching the first gate film to leave notches at the interface with the tunneling dielectric film and at the edge of the device, and etching the tunneling dielectric film.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1C (Prior Art) show the cross section of a flash memory device and a process of making the device.

FIGS. 2A-2B (Prior Art) show movement of electrons of a flash memory device during programming (FIG. 2A) and erasing (FIG. 2B).

FIG. 3A shows the top view of a flash memory device.

FIG. 3B shows the side view of the flash memory device in FIG. 3A cut along the line AA′.

FIG. 3C shows the side view of the flash memory device in FIG. 3A cut along the line BB′.

FIG. 4A shows the top view of a flash memory device of an embodiment of the present invention.

FIG. 4B shows the side view of the flash memory device in FIG. 4A cut along the line CC′.

FIGS. 5A-5F shows the process flow of an embodiment of the present invention in making a flash memory device.

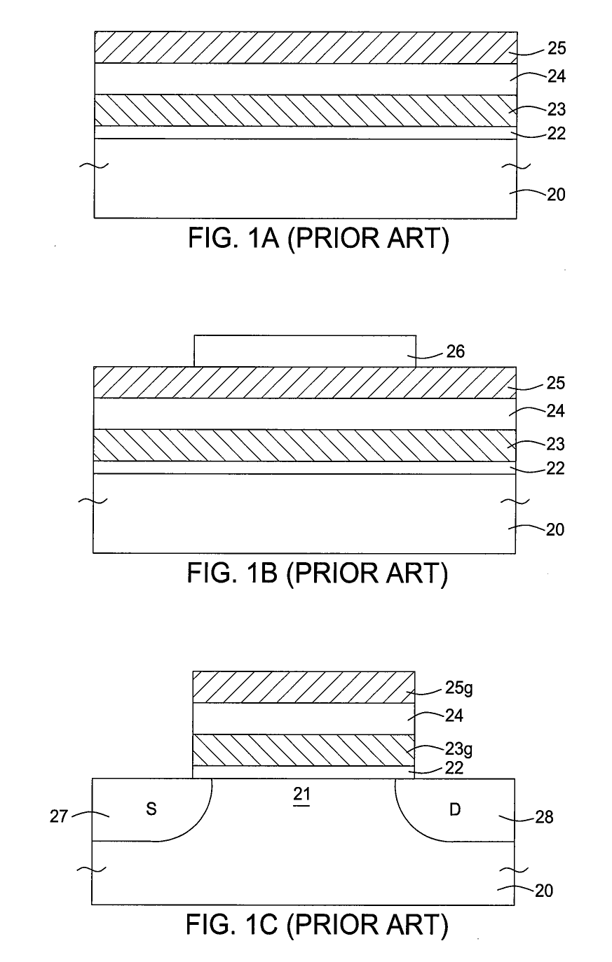

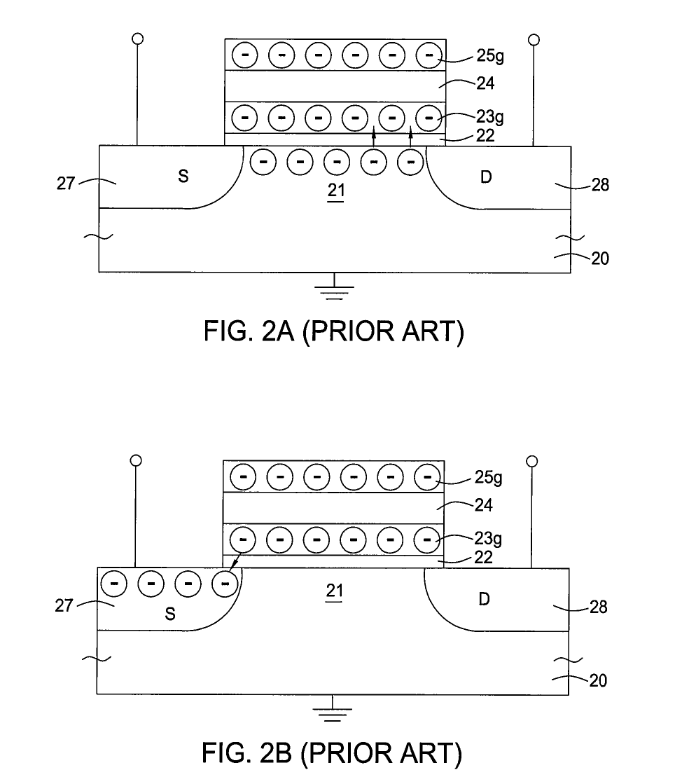

### DETAILED DESCRIPTION

The embodiments present invention generally relates a semiconductor flash memory device and a method of making the flash memory device with increased gate coupling ratio.

As described earlier, gate coupling ratio can be increased by either increasing C_{cg} or reducing other capacitances, such as C_{fs}, C_{fw}, C_{fd}, and Cₘₒₛ. Typically, C_{fs}, C_{fw} and C_{fd} are much smaller (<10%) than C_{cg} and Cₘₒₛ. Increasing C_{cg} or decreasing Cₘₒₛ would have larger impacts in increasing gate coupling ratio (CR), compared to decreasing C_{fs}, C_{fw} or C_{fd}.

C_{cg} is the capacitance between the control polysilicon gate and the floating silicon gate. It is a function of the surface area of the interlayer oxide (A_{ILO}) between the control polysilicon gate and the floating polysilicon gate, and interlayer oxide thickness (t_{ILO}) as shown in equation (2).
C_{cg}=ε_{ILO}A_{ILO}/t_{IL} (2)
Where, ε_{ILO} is the dielectric constant of the interlayer oxide (ILO).

C_{cg} can be increased by increasing ε_{TNO} or A_{TNO}, or by decreasing t_{TNO}. For conventional flash cell, the thickness of the tunneling oxide is between about 50 Å to about 100 Å, the thickness of the floating polysilicon gate is between about 500 Å to about 2000 Å, the interlayer oxide is a composite of about 50 Å to 200 Å nitride layer on top of a 100 Å to about 300 Å oxide layer, and the thickness of the control gate is about 3000 Å to about 6000 Å. Using a nitride/oxide composite increases the ε_{ILO}, but it also limits how low the t_{ILO} can be. Increasing A_{ILO} would increase the cell size and reduce the device density on the chip. Therefore, the alternative is to reduce Cₘₒₛ.

Cₘₒₛ is the capacitance between the channel region 21 and the floating gate 23 (or the capacitance of the MOS transistor). It is a function of the surface area of the tunneling oxide (A_{TNO}) between the floating polysilicon gate and the channel region 21, and tunneling oxide thickness (t_{TNO}) as shown in equation (3).
Cₘₒₛ=ε_{TNO}A_{TNO}/t_{TNO} (3)
Where, ε_{TNO} is the dielectric constant of the tunneling oxide (TNO).

Cₘₒₛ can be reduced by lowering ε_{TNO} or A_{TNO}, or by increasing t_{TNO}. Lowering ε_{TNO} requires changing the gate material, which is very complicated and risky. Increasing t_{TNO} is not possible since the tunneling oxide needs to remain thin (no greater than about 100 Å) to achieve the Fowler-Nordheim tunneling. Therefore, the most likely way to reduce Cₘₒₛ is by reducing A_{TNO}.

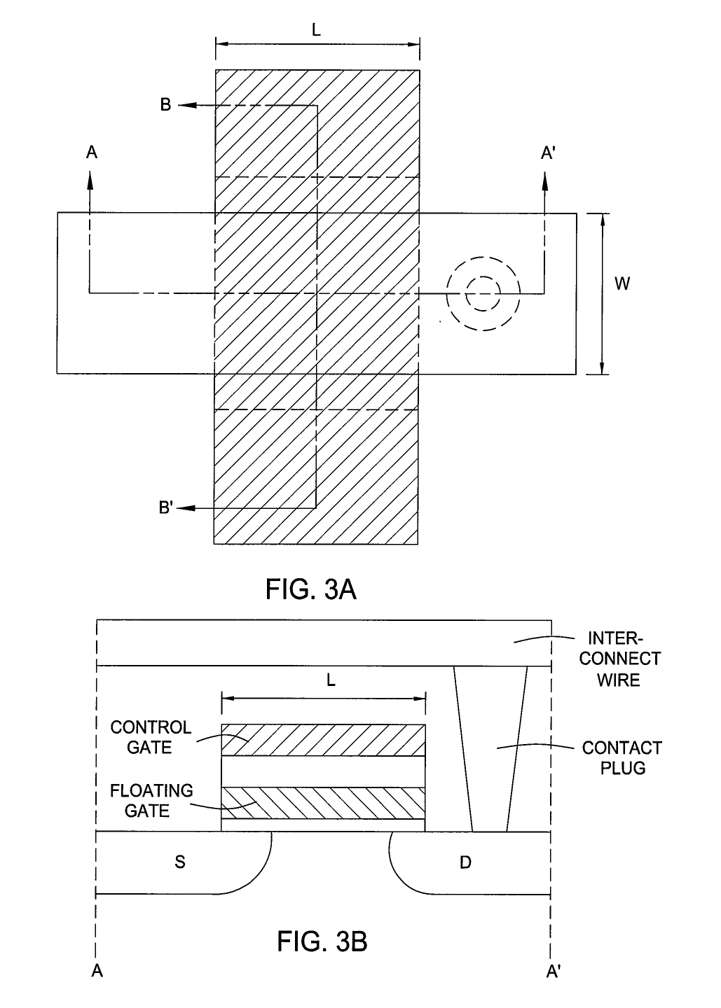

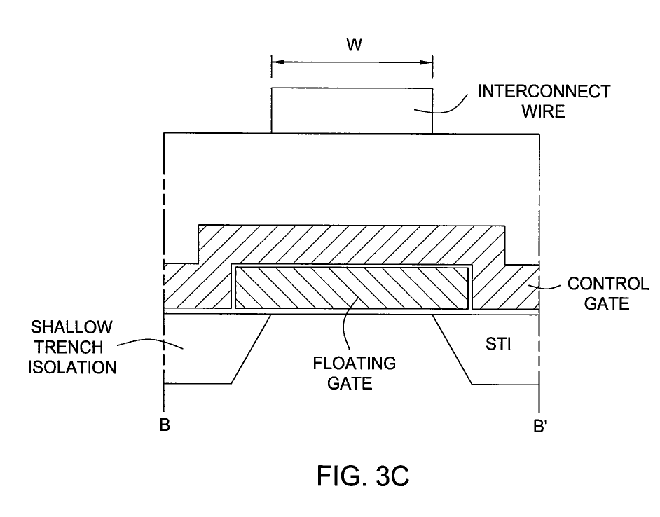

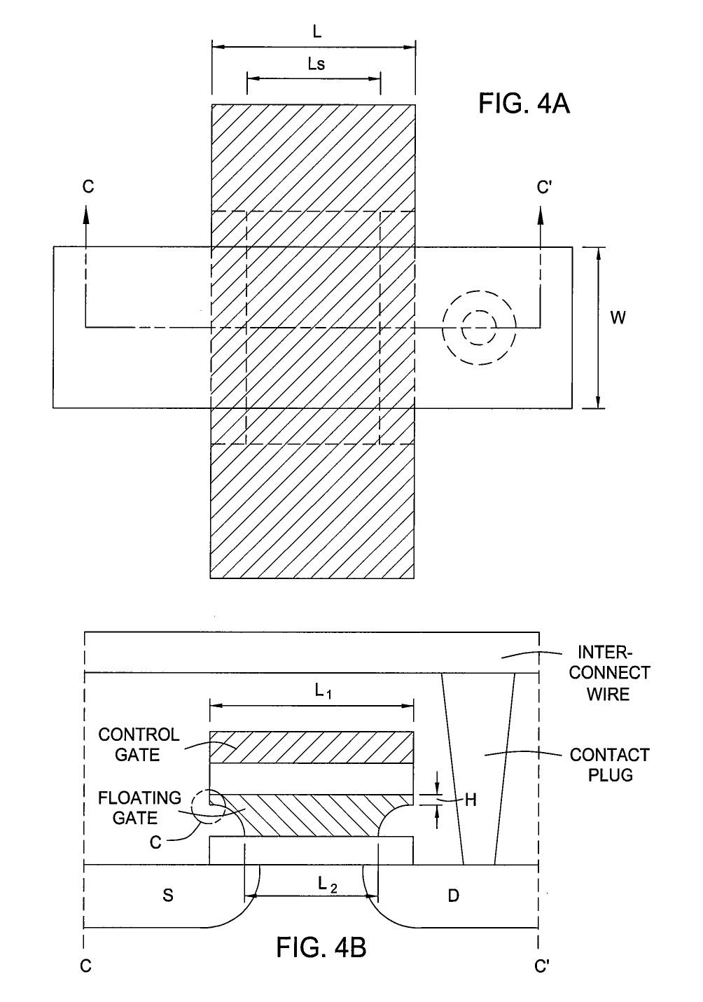

FIG. 3A shows the top view of a flash cell which an interconnecting wire runs across it. L is the width of the flash cell and W is the width of the interconnecting wire. FIG. 3B shows the side view of the flash cell in FIG. 3A cut along the line AA′. The widths of the control gate and floating gate are both L. The source and drain regions in the silicon are also shown in FIG. 3B. FIG. 3C shows the side view of the flash cell in FIG. 3A cut along the line BB′. The width of the interconnect wire is W. As shown in FIG. 3C, shallow trench isolation (STI) regions are in the silicon to isolate adjacent devices. The area of tunneling oxide A_{TNO} that would affect the device performance equals to L times W (see FIG. 3A).
A_{TNO}=L*W (4)
Embodiments of the invention describe one method of reducing the surface area of the tunneling oxide (A_{TNO}) by forming a notched floating polysilicon gate. FIG. 4A shows the top view of a flash cell with notched floating polysilicon. FIG. 4B shows the side view of the flash cell in FIG. 4A cut along the line CC′. The width of the tunneling oxide under the floating poly gate (Lₛ) in FIGS. 4A and 4B is narrower than the width of the tunneling oxide under of floating poly gate (L) in FIGS. 3A and 3B. The surface area of the tunneling oxide of the new cell that would affect the device performance (A_{TNO, new}) is reduced to:
A_{TNO, new}=Lₛ*W<A_{TNO, old}=L*W (5)
Where, A_{TNO, old} is the area of tunneling oxide of the cell in FIGS. 3A and 3B that would does not have the notched floating polysilicon.

Therefore, Cₘₒₛ, which is the capacitance between the channel region and the floating polysilicon gate, of the new flash cell (Cₘₒₛ, new) is smaller than Cₘₒₛ of the old flash cell (Cₘₒₛ, old).
C_{mos, new}<C_{mos, old} (6)

The amount of Cₘₒₛ reduction is proportional to the reduction in the poly width next to the tunneling oxide. With this notched floating polysilicon gate, C_{cg}, the capacitance between the control gate and the floating gate, and C_{fw}, the capacitance between the substrate and the floating gate, remain unchanged, since they are unaffected by the area change in floating poly gate. C_{fs}, the capacitance between the source and the floating gate, and C_{fd}, the capacitance between the drain and the floating gate, are reduced because the overlap is smaller and the fringing fields are reduced. It is important to note that the polysilicon at corner(s) C, in FIG. 4B, of floating polysilicon right under the interlayer oxide needs to extend to the edge of the interlayer oxide to ensure that C_{cg} is not reduced due to the loss of floating polysilicon gate width. In other words, the height H of the polysilicon at the corners C must be greater than 0.

The notched floating poly gate can increase the gate coupling ratio without increasing the flash cell size and also does not require additional photoresist mask. The notched poly gate can be formed by wet etching or drying etching. An exemplary method of forming a notched polysilicon structure is described in the commonly assigned U.S. Pat. No. 6,551,941, titled “Method of Forming a Notched Silicon-Containing Gate Structure”, issued Apr. 22, 2003, which method is incorporated by reference herein.

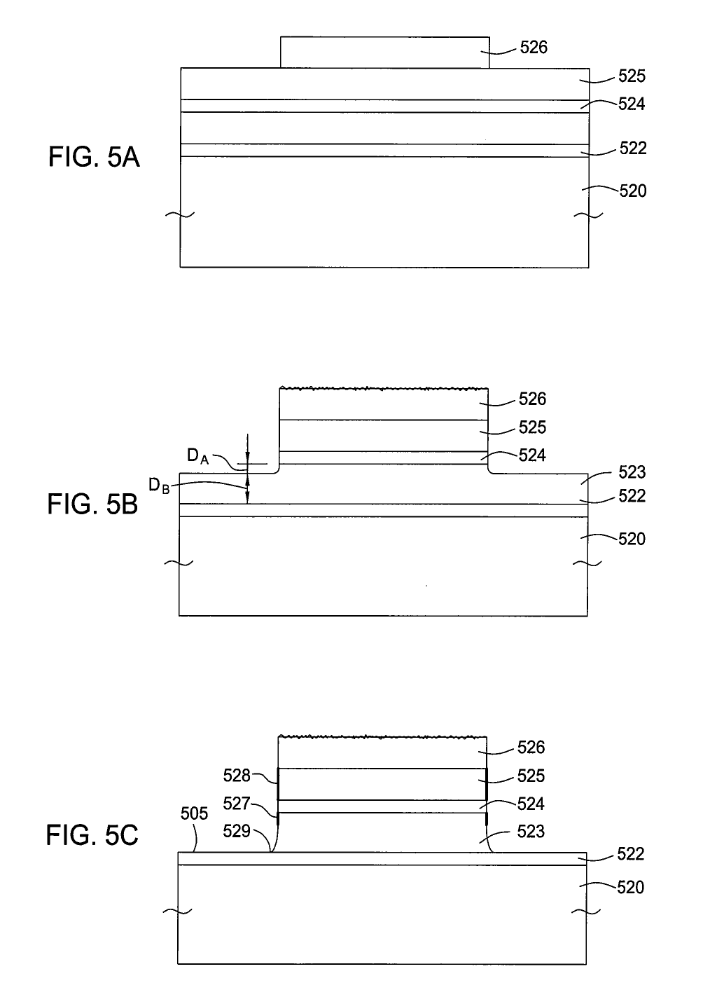

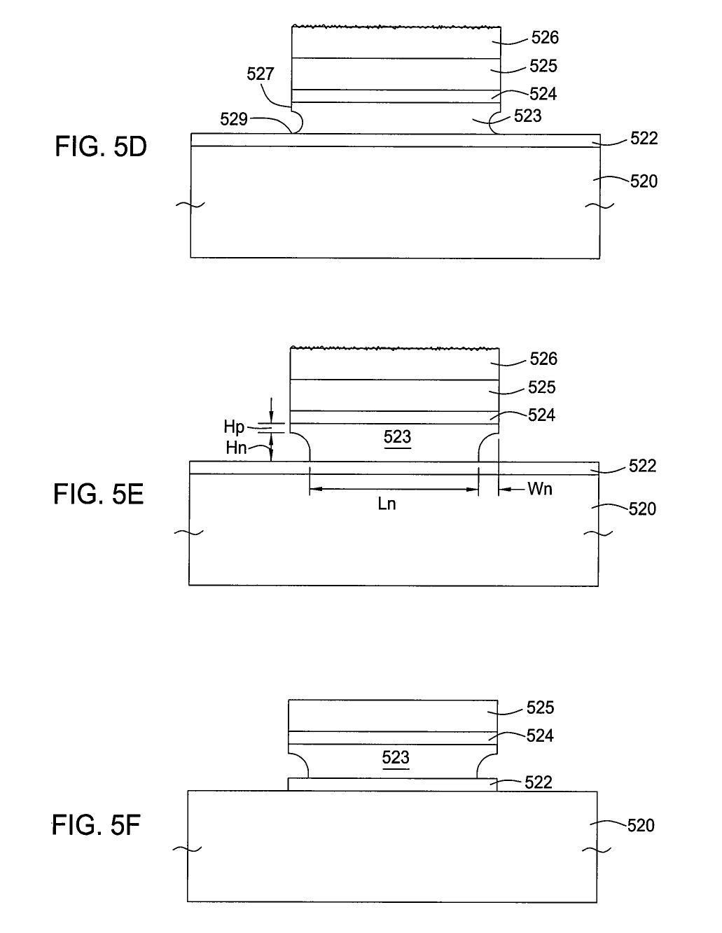

FIG. 5A shows the flash cell gate stack with patterned photoresist 526 prior to gate stack etch. The gate stack includes a control polysilicon gate layer 525, an interlayer oxide 524, a floating polysilicon gate layer 523, and a tunneling oxide layer 522. The gate stack is on substrate 520. The tunneling oxide layer 522 could be thermally grown or deposited by chemical vapor deposition. It could be silicon dioxide, nitrided silicon oxide, or other applicable gate dielectrics. The thickness of the tunneling oxide 522 is between about 50 Å to about 100 Å. The floating polysilicon gate layer 523 could be deposited by chemical vapor deposition and the thickness is in the range of 500 Å to about 2000 Å. The floating polysilicon gate layer 523 could be lightly doped with an impurity, such as phosphorus or arsenic, to increase its etch selectivity compared to the control poly silicon gate layer. The thickness of the interlayer oxide 524 could be a composite of dielectric layers and can be thermally grown or deposited by chemical vapor deposition. In one embodiment, the interlayer oxide 524 is a composite of a nitride layer, in the thickness range of 50 Å to 200 Å, on top of an oxide layer, in the thickness range of 100 Å to about 300 Å. The control polysilicon gate layer 525 could be deposited by chemical vapor deposition and the thickness is in the range of between about 3000 Å to about 6000 Å. An exemplary etch process to create notched floating polysilicon gate is described below.

FIG. 5B shows that the control polysilicon gate 525 and the interlayer oxide 524 have been etched. The etching processes are well known in the industry. In additional, A small amount of the floating posilicon layer 523 has been an-isotropically etched to a depth of D_{A} during the first floating polysilicon etch step, which is anisotropic. After performance of the first floating polysilicon etch step, a partial layer of unetched polysilicon gate material 523 remained on the substrate 520. In this case, the partial polysilicon layer had a thickness D_{B}. Since the outer surface of the polysilicon etched to depth D_{A} is passivated during etching to form a protective layer, this depth D_{A} limits the height of a notch subsequently etched into the remaining polysilicon partial layer. Thus, height D_{B} is representative of the notch height.

Exemplary process conditions used during the first polysilicon etch step are as follows: a plasma source gas comprising 100 sccm CF₄, 20 sccm Cl₂, and 30 sccm N₂; a plasma source power of 600 W; a substrate bias power of 60 W; a process chamber pressure of 4 mTorr; and a substrate temperature of about 50° C. In addition to etching the polysilicon, this source gas provides for the formation of a nitrogen-containing passivation layer on the surface of the etched polysilicon. This passivation layer is created by the build-up of non-volatile etch byproducts on upper floating polysilicon sidewalls 527 and control polysilicon sidewalls 528 which are exposed during etching.

Referring to FIG. 5C, a second polysilicon etch step is performed to etch the remaining portion of polysilicon gate layer 523. Lower sidewalls 529 of floating polysilicon gate layer 523 could be formed and an upper surface 505 of silicon oxide gate dielectric layer 522 is exposed during this second etching. Exemplary process conditions for the second polysilicon etch step are as follows: a plasma source gas comprising 160 sccm HBr, 20 sccm Cl₂, and 8 sccm He/O₂; a plasma source power of 1000 W; a substrate bias power of 40 W; a process chamber pressure of 50 mTorr; and a substrate temperature of about 50° C. Emissivity is checked to provide an endpoint indication for the etch step, and the etch cycle is adjusted in accordance with a change in the emissivity, using techniques known in the art.

As shown in FIG. 5C, a substantial amount of the passivation layers that are formed on the upper sidewalls 527 of floating polysilicon gate layer 523 and sidewalls 528 of control polysilicon gate layer 525 during the first polysilicon etch step are still in place after the second polysilicon etch step. In fact, the passivation layers on upper polysilicon sidewalls 527 and sidewalls 528 are typically thickened by further deposition of etch byproducts during the second polysilicon etch step. The etch byproducts which form during the second etch step and which increase surface passivation may include, but are not limited to, silicon bromide, silicon oxide, and silicon chloride. These byproducts are added to silicon nitride, silicon chloride, and carbon/nitrogen compound mixtures present from the first polysilicon etch step.

As shown in FIG. 5C, after performance of the second polysilicon etch step, the lower sidewalls 529 of floating polysilicon gate layer 523, in which notches are to be formed, are exposed, with only a thin layer of passivating material being present. The thick passivation layer formed during the first polysilicon etch step forms a protective collar over the upper sidewalls 527 of polysilicon gate layer 523 and sidewalls 528 of polysilicon gate layer 525, which shields the upper portion of polysilicon gate layer 523 and the control polysilicon gate layer 525 from etching.

Referring to FIG. 5D, an optional second passivating step utilizing a plasma source gas which includes nitrogen is then performed. Exemplary process conditions for the second passivating step are as follows: a plasma source gas comprising 160 sccm HBr, 20 sccm Cl₂, 8 sccm He/O₂, and 10 sccm N₂; a plasma source power of 1000 W; a substrate bias power of 40 W; a process chamber pressure of 50 mTorr; and a substrate temperature of 50° C. The purpose of the second passivating step is to build up the passivation layer on polysilicon sidewalls 527, 529 and 528 in isolated areas of the substrate, in order to protect these sidewalls from over-aggressive notch etching during the subsequent notch etch step. Since some etching takes place during the passivating step, footings remaining at the base of the polysilicon gate layer 524 are typically removed at this time. Passivation layers formed on polysilicon sidewalls 527, 529 and 528 in isolated areas of the substrate during the passivating step are thicker than passivation layers formed on polysilicon sidewalls 527, 529 and 528 in dense areas of the substrate, since isolated sidewall surfaces are more accessible and etching action is minor.

After the passivating step, an isotropic notch etching step was performed to remove polysilicon gate material and form notches in the area of the lower polysilicon sidewalls 529, which have a much thinner passivation layer than the upper polysilicon sidewalls 527 and sidewalls 528. Exemplary process conditions for the notch etch step are as follows: a plasma source gas comprising 160 sccm HBr, 20 sccm Cl₂, and 8 sccm He/O₂; a plasma source power of 1000 W; a substrate bias power of 40 W; a process chamber pressure of 50 mTorr; and a substrate temperature of about 50° C.

FIG. 5E shows the polysilicon gate structure 520 after notch etching. The etch provides excellent etch uniformity across the surface of the substrate, resulting in very consistent remaining notch heights (Hₙ), notch widths (Wₙ) and gate lengths (L_{g}) between dense and isolated areas of the substrate. The remaining floating polysilicon height (Hₚ) is greater than 0. The notch width (Wₙ), the notch height (Hₙ), and the gate length (L_{g}) can be controlled by adjusting etch time of the isotropic etch. Longer etch time will increase the Hₙ and Wₙ, and will decrease Lₙ. Shorter Lₙ will result in lower Cₘₒₛ and higher CR (gate coupling ratio). However, the Lₙ should not become so short that the gate stack loses its mechanical integrity, such as greater than 5 Å, or that the channel formation (between source and drain) becomes impossible, such as greater than 5 Å. FIG. 5F shows the flash cell after the tunneling oxide is etched. The tunneling oxide could have the same width as the control polysilicon gate (as shown in FIG. 5F) or the floating polysilicon gate.

Using the notched floating polysilicon gate to improve the coupling ratio of flash cell is easy to do, based on the exemplary process described. Lowering the gate coupling ratio allows a reduction in the control gate voltage, which could reduce the power consumption and also could reduce the power source areas on the chip that are dedicated to produce the control gate voltage. It also has the advantages of not requiring an additional mask layer with smaller dimensions. As device size scales down and the lithography requirement become more stringent, this method would become even more valuable for not requiring an additional mask layers with smaller dimensions.

While the foregoing is directed to embodiments of the present invention, other and further embodiments of the invention may be devised without departing from the basic scope thereof, and the scope thereof is determined by the claims that follow.

1. A method of increasing the gate coupling ratio of a semiconductor flash memory cell, comprising:
depositing a tunneling dielectric film on said semiconductor substrate;
depositing a first gate film on said tunneling dielectric film;
depositing an interlayer dielectric film on said first gate film;
depositing a second gate film on said interlayer dielectric film;
patterning the semiconductor substrate after the second gate film is deposited;
etching the second gate film and the interlayer dielectric film;
etching the first gate film to leave notches at a shared surface area with the tunneling dielectric film and at the edge of the cell; and
etching the tunneling dielectric film.

2. The method of claim 1, further comprising:
creating a source region and a drain region in the semiconductor substrate.

3. The method of claim 1, wherein the tunneling dielectric film is made of silicon dioxide.

4. The method of claim 1, wherein the thickness of the tunneling dielectric film is between about 50 Å to about 200 Å.

5. The method of claim 1, wherein the first gate film is made of polysilicon.

6. The method of claim 1, wherein the thickness of the first gate film is between about 500 Å to about 2000 Å.

7. The method of claim 5, wherein the polysilicon is doped with impurity.

8. The method of claim 7, wherein the impurity is germanium.

9. The method of claim 1, wherein the interlayer dielectric film is a composite of silicon dioxide and silicon nitride.

10. The method of claim 1, wherein the thickness of the interlayer dielectric film is between about 150 Å to about 500 Å.

11. The method of claim 9, wherein the thickness of silicon dioxide is between about 100 Å to about 300 Å and the thickness of silicon nitride is between about 50 Å to about 200 Å.

12. The method of claim 1, wherein the second gate film is made of polysilicon.

13. The method of claim 1, wherein the thickness of the second gate film is between about 3000 Å to about 6000 Å.

14. The method of claim 1, wherein the first gate film has a width greater than 5 Å at the shared surface area with the tunneling dielectric film.

15. The method of claim 1, wherein etching the first gate film further comprises:
a first etch that is anisotropic; and
a second etch that is isotropic.

16. The method of claim 15, wherein the etch gases of the first etch comprises CF₄, Cl₂ and N₂.

17. The method of claim 15, wherein the etch gases of the second etch comprises HBr, Cl₂, He and O₂.

18. The method of claim 15, wherein the widths and heights of the notches in the first gate film and at the shared surface area with the tunneling dielectric film are controlled by the etch time of the second etch.

19. The method of claim 18, wherein the gate coupling ratio increases with the widths of the notches in the first gate film.

20. The method of claim 1, wherein the notches formed in the first gate film extends to an edge of the interlayer dielectric film.

21. The method of claim 2, the source region and the drain region created in the substrate extends to an area inward the notches.

22. The method of claim 1, wherein the step of etching the tunneling dielectric film further comprises:
etching the tunneling dielectric film to have a first end formed on a source region in the semiconductor substrate and a second end formed on a drain region in the semiconductor substrate.

23. The method of claim 1, wherein the height of the notches are smaller than a thickness of the first gate dielectric film.
